(19) United States
(12) Patent Application Publication
(10) Pub. No.: US 2016/0230307 A1
(43) Pub. Date: Aug. 11, 2016

(54) APPARATUS AND METHODS FOR PRODUCING SILICON-INGOTS

(71) Applicant: SOLARWORLD INDUSTRIES AMERICA INC., Hillsboro, OR (US)

(72) Inventors: Nathan STODDARD, Beaverton, OR (US); Carroll MURPHY, Washougal, WA (US); Thomas KURRASCH, Portland, OR (US); Bjoern SEIPEL, Portland, OR (US)

(21) Appl. No.: 14/614,861

(22) Filed: Feb. 5, 2015

(51) Int. Cl. C30B 11/10; C30B 29/06; C30B 11/00

(52) U.S. Cl. CPC C30B 11/10; C30B 11/006; C30B 11/003; C30B 29/06; C30B 11/001

(57) ABSTRACT

Apparatus and method for a production of silicon ingots, such as crucible-less production of silicon ingots, where a support with a seed layer and a liquid layer is gradually lowered in a temperature field with a vertical gradient to solidify the liquid layer in a controlled way.

### TECHNICAL FIELD

The present disclosure relates to an apparatus and a method for the production of ingots.

### BACKGROUND

Techniques for bulk growth of crystals, such as those made from silicon, include for example, float zone (FZ), Czochralski (Cz) and multicrystalline (mc) growth. In each of these conventional methods, there are challenges to growing predetermined shapes of ingots, such as ingots having a square shape, and monitoring and control of the crystal growth interface.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In some embodiments, the present disclosure relates to an apparatus for the production of ingots, the apparatus including a chamber to provide a controllable atmosphere, where the chamber has a top and a bottom spaced apart from each other in a longitudinal direction; a rotatable support for supporting a seed layer, wherein the rotatable support is movable in the longitudinal direction relative to the chamber, at least one unit for controlling a temperature field in a given volume of growth (V_{GR}) in the chamber, wherein the temperature field has a temperature gradient in the longitudinal direction, and a feeding apparatus for controllable feeding of material onto the seed layer. In some embodiments, the present disclosure relates to methods for the production of ingots, the methods including: providing an apparatus, the apparatus including: a chamber to provide a controllable atmosphere, at least one unit for controlling a temperature field with a temperature gradient in a longitudinal direction in a given volume of growth (V_{GR}) inside the chamber, a rotatable support for a seed layer, the rotatable support being movable in the longitudinal direction inside the chamber, and a controllable feeding apparatus for providing feedstock; providing a seed layer on the rotatable support, wherein the seed layer has a predetermined cross-sectional area; moving the rotatable support, such that the seed layer is located at a predetermined position within the volume of growth (V_{GR}); generating a temperature field with a predetermined vertical temperature gradient within the volume of growth (V_{GR}); providing an initial layer of melted silicon to substantially cover the seed layer; rotating and lowering the rotatable support while solidifying the layer of liquid feedstock to form an ingot having a cross-sectional area; and adding more liquid feedstock from the feeding apparatus.

### BRIEF DESCRIPTION OF THE DRAWINGS

The manner in which the objectives of the present disclosure and other desirable characteristics may be obtained is explained in the following description and attached drawings in which:

FIG. 1 is an illustration of a sectional view of an embodiment of the apparatus of the present disclosure.

### DETAILED DESCRIPTION

In the following description, numerous details are set forth to provide an understanding of the present disclosure. However, it may be understood by those skilled in the art that the methods of the present disclosure may be practiced without these details and that numerous variations or modifications from the described embodiments may be possible.

At the outset, it should be noted that in the development of any such actual embodiment, numerous implementation-specific decisions may be made to achieve the developer's specific goals, such as compliance with system related and business related constraints, which will vary from one implementation to another. Moreover, it will be appreciated that such a development effort might be complex and time consuming but would nevertheless be a routine undertaking for those of ordinary skill in the art having the benefit of this disclosure. In addition, the composition used/disclosed herein can also comprise some components other than those cited. In the summary and this detailed description, each numerical value should be read once as modified by the term “about” (unless already expressly so modified), and then read again as not so modified unless otherwise indicated in context. The term about should be understood as any amount or range within 10% of the recited amount or range (for example, a range from about 1 to about 10 encompasses a range from 0.9 to 11). Also, in the summary and this detailed description, it should be understood that a range listed or described as being useful, suitable, or the like, is intended to include support for any conceivable sub-range within the range at least because every point within the range, including the end points, is to be considered as having been stated. For example, “a range of from 1 to 10” is to be read as indicating each possible number along the continuum between about 1 and about 10. Furthermore, one or more of the data points in the present examples may be combined together, or may be combined with one of the data points in the specification to create a range, and thus include each possible value or number within this range. Thus, (1) even if numerous specific data points within the range are explicitly identified, (2) even if reference is made to a few specific data points within the range, or (3) even when no data points within the range are explicitly identified, it is to be understood (i) that the inventors appreciate and understand that any conceivable data point within the range is to be considered to have been specified, and (ii) that the inventors possessed knowledge of the entire range, each conceivable sub-range within the range, and each conceivable point within the range. Furthermore, the subject matter of this application illustratively disclosed herein suitably may be practiced in the absence of any element(s) that are not specifically disclosed herein.

The present disclosure relates to providing an apparatus and a method to facilitate the production of ingots.

In some embodiments, the present disclosure is directed to an apparatus for the production of ingots, the apparatus comprising: a chamber to provide a controllable atmosphere, wherein the chamber has a top and a bottom spaced apart from each other in a vertical, i.e. longitudinal direction, a support (such as a rotatable support) for supporting a seed layer, wherein the support is movable in the longitudinal direction relative to the chamber, at least one means for controlling a temperature field in a given volume of growth in the chamber, wherein the temperature field has a temperature gradient in the longitudinal direction, and a feeding apparatus for controllable feeding of material onto the seed layer.

In some embodiments, the present disclosure relates to methods for the production of ingots, where the methods may comprise one or more of the following actions: providing an apparatus with a chamber to provide a controllable atmosphere; at least one means for controlling a temperature field with a temperature gradient in a longitudinal direction in a given volume of growth inside the chamber; a support for a seed layer, the support being movable, such as rotatable and/or movable in the longitudinal direction inside the chamber (with respect to the internal hot zone); and a controllable feeding apparatus for providing feedstock; providing a seed layer on the support, wherein the seed layer roughly defines a cross-sectional area of an ingot to be produced; moving the support, such that the seed layer is located at a predetermined position within the volume of growth; generating a temperature field with a predetermined vertical temperature gradient within the volume of growth; either providing an initial layer of melted silicon to substantially cover the seed layer, or providing feedstock on the seed layer by way of the feeding apparatus, wherein the feeding of feedstock and the temperature field within the volume of growth are controlled such that, substantially, the entire seed layer is covered with a layer of liquid feedstock, rotating the support while lowering the support with respect to the hot zone in concert with the solidification of the layer of liquid feedstock, being cooled from below.

In some embodiments, the methods for the production of ingots of the present disclosure further comprise independently controlling a growth behavior of one or more positions on a perimeter of an ingot. For example, in some embodiments, in order to control the cross-sectional shape of a rotating circular ingot (i.e., to keep it as circular as possible, and to avoid nodes, bumps or spirals in the growing ingot), the growth behavior of the perimeter of the ingot may be controlled by one or more independently controlled heaters (such as an inductive heater having a rapid response time) positioned near the edge of the ingot that is capable of rapidly heating up and cooling down to provide phase boundary adjustments to different parts of the perimeter as the ingot rotates by the heater. In some embodiments, the growth behavior of the perimeter of the ingot may be controlled by positioning one or more independently movable insulation or heat shields in the vicinity of one or more positions on the perimeter of the ingot in order to rapidly change the radiation view factor for different parts of the perimeter as they pass by the moving parts. In some embodiments, the growth behavior of the perimeter of the ingot may be controlled by positioning one or more independently controlled gas inlets supplying either cool gas (such as a gas that is at a temperature that is at least about 50° C. cooler than the surface of the ingot (e.g., the surface of the ingot at which the gas is being directed), or at least about 80° C. cooler than the surface of the ingot, for example, a gas that is at a temperature in a range of from about 80° C. to about 200° C. cooler than the surface of the ingot, or a temperature in a range of from about 100° C. to about 150° C. cooler than the surface of the ingot) or superheated gas (such as a gas that is at a temperature that is at least about 50° C. warmer than the surface of the ingot (e.g., the surface of the ingot at which the gas is being directed), or at least about 80° C. warmer than the surface of the ingot, for example, a gas that is at a temperature in a range of from about 80° C. to about 200° C. warmer than the surface of the ingot, or a temperature in a range of from about 100° C. to about 150° C. warmer than the surface of the ingot) directed at or in the vicinity of the phase boundary between the solidified ingot and the liquid layer of feedstock and where the strength of the gas jet stream can be rapidly modified in response to a signal measured on the perimeter of the ingot as it rotates by.

In some embodiments, the present disclosure relates to providing an apparatus for the production of ingots with at least one means for generating a temperature gradient in a longitudinal direction inside a chamber and a rotatable support for supporting a seed layer, which support is movable in the direction of the temperature gradient, and a feeding apparatus for controllable feeding of material onto the roughly flat seed crystal layer.

The apparatus may be used for the production of crystallized materials, such as, for example, silicon ingots. In some embodiments, the apparatus may be used for a crucibleless production of ingots. For example, the liquid feedstock on the seed layer may be freestanding, i.e. there are no crucibles, vessels or cold wall crucibles for containing the liquid feedstock. In some embodiments, the methods of the present disclosure may be used to crystallize materials other than silicon. For example, the other materials that may be crystallized by the methods of the present disclosure, include (but are not limited to) germanium, gallium arsenide, silicon germanium, and other compounds and oxides having a metastable or stable liquid phase. In some embodiments, the methods of the present disclosure may be used to crystallize compounds/materials where the concentration of the constituents in the melt change over time (e.g. through evaporation or preferential incorporation in the solid), since the management of the composition of the constant influx of new molten material can be used to maintain a constant composition in both the liquid and the solid.

In some embodiments, the seed layer may comprise at least one seed plate arranged on the rotatable support. The seed plate may be made of any desired material, such as silicon, which may have a monocrystalline structure. In some embodiments, the seed plate may be made of monocrystalline silicon, or may be made of an ingot produced according to the methods of the present disclosure.

The seed layer can comprise several seed plates or several seed crystals. The seed plates may be arranged in a regular pattern on the rotatable support. In some embodiments, the seed plates may form a tiling of a predescribed area on the rotatable support. The seed plates may have a given crystal structure, or a given orientation.

In some embodiments, the seed layer may have a cross-sectional area corresponding to that of the ingots to be produced. For example, the seed layer may have the same cross-sectional shape as the ingots to be produced or the cross-sectional area of the seed layer may be within 20% of that of the final ingot. In some embodiments, larger variations from the seed cross-section to the final cross-section may be achieved (for example, where the cross-sectional area of the seed layer may be within about 40 to about 80% of that of the final ingot); however, in such embodiments, without extensive control (i) the tapered ingot section may increase yield loss and may decrease throughput, and (ii) the congruency and stability of an ingot shape may not be maintained over large changes in cross-sectional area.

In some embodiments, an average diameter of the predetermined cross-sectional area of the seed layer may be smaller than an average diameter of the cross-sectional area of the ingot. For example, an average diameter of the predetermined cross-section of the seed layer may be at least about 5% smaller, such as from about 5% to about 50% smaller, or from about 10% to about 40% smaller, than an average diameter of the cross-section of the ingot. As used herein the term “diameter” may, for example, refer to not only circular cross-sections, but also, more generally, refer to the typical lateral dimension of a general cross-sectional shape (e.g. the side length of a square).

In some embodiments, an average diameter of the predetermined cross-section of the seed layer may be larger than an average diameter of the cross-section of the ingot. For example, an average diameter of the predetermined cross-section of the seed layer may be at least about 5% larger, such as from about 5% to about 50% larger, or from about 10% to about 40% large, than an average diameter of the cross-section of the ingot. Small amounts of shape change may be allowable between the seed cross-section and the stable ingot cross-section. For example, a seed shape may have a more exaggerated corner profile or a tighter corner radius than the nominal grown crystal section.

In some embodiments, it may be desirable to start with one seed cross-sectional shape and to transition over time to an entirely different cross-section. In some embodiments, the process control is such that the starting seed cross-sectional shape does not transition over time to an entirely different cross-section.

In some embodiments, the seed layer may have a cross-sectional area of at least about 0.04 m², such as at least about 0.1 m², or at least about 0.2 m², or at least about 0.4 m². The seed layer may be any desired shape, such as circular, rectangular, square, or polygonal. In some embodiments, the seed layer may have one or more flat side lengths, such as one or more flat side lengths that are integer multiples of a wafer size.

In some embodiments, the methods of the present disclosure relate to a method for making square ingots (optionally without any rotation of the ingots), the method comprising: providing an apparatus, the apparatus comprising: a chamber to provide a controllable atmosphere, at least one means for controlling a temperature field with a temperature gradient in a longitudinal direction in a given volume of growth (V_{GR}) inside the chamber, a support for a seed layer, the support being movable in the longitudinal direction inside the chamber and having a longitudinal heat removal, and a controllable feeding apparatus for providing feedstock; providing a seed layer on the support, wherein the seed layer has a predetermined cross-sectional area; moving the support, such that the seed layer is located at a predetermined position within the volume of growth (V_{GR}); generating a temperature field with a predetermined vertical temperature gradient within the volume of growth (V_{GR}); providing an initial layer of melted silicon to substantially cover the seed layer; lowering the rotatable support while solidifying the layer of liquid feedstock to form an ingot having a cross-sectional area; and adding more liquid feedstock from the feeding apparatus. In some embodiments, an average lateral dimension of the predetermined cross-section of the seed layer is at least 5% larger than an average lateral dimension of the cross-section of the ingot. In some embodiments, an average lateral dimension of the predetermined cross-section of the seed layer is at least 5% smaller than an average lateral dimension of the cross-section of the ingot.

In some embodiments, the outer perimeter of the seed layer may have rounded corners. For example, the corners may have radii (r) of at least about 1 mm, such as at least about 3 mm, at least about 10 mm or at least about 20 mm.

In some embodiments, the at least one means for controlling the temperature field in the chamber may comprise at least one top heating apparatus arranged above the rotatable support for the seed layer. In some embodiments, the at least one means for controlling the temperature field comprises one or more independently controlled heaters, such as one or more independently controlled heaters arranged near and/or above the rotatable support for the seed layer.

The heating apparatus may be arranged on the opposite side of the seed plate from the rotatable support. It may be controllable, for example, by a control device. The control device may be part of an open loop or a closed loop control system. The heating apparatus may be inductive or resistive.

In some embodiments, the top heating apparatus may be designed to generate a temperature field with a temperature gradient in a direction perpendicular to the longitudinal direction.

In some embodiments, the at least one top heating apparatus comprises at least two heating loops, which are independently controllable. Each of the heating loops may be connected to a power source providing at least one of a DC power signal and an AC power signal

In some embodiments, the at least two heating loops may be arranged concentrically. The at least two heating loops have different perimeters, such that one heating loop forms an outermost heating loop, and wherein the outermost heating loop has a weaker heating power than at least one other heating loop.

In some embodiments, the at least one means for controlling the temperature field may comprise at least one bottom cooling apparatus arranged below the support for the seed layer. The top heating apparatus and the bottom cooling apparatus may be arranged on opposite sides of the seed layer with respect to the longitudinal direction. The bottom cooling apparatus may be controllable in a manner that allows for a controlled variation in the magnitude of heat removal.

In some embodiments, at least one of the top heating apparatus and the bottom cooling apparatus is designed such that a lateral temperature gradient in a volume of growth is at most about 5 K/cm, such as at most about 1 K/cm, or at most about 10⁻¹ K/m. In some embodiments, the temperature gradient may be controllable.

In some embodiments, the temperature gradient in the longitudinal direction may be controllable. For example, the temperature gradient in the longitudinal direction may be controlled to be a value in the range of from about 100 K/m to about 10000 K/m, such as a value in the range of from about 300 K/m to about 3000 K/m.

In some embodiments, the apparatus may comprise at least one perimeter heater. The perimeter heater may have an inner perimeter matching or nearly matching an outer perimeter of the seed layer in shape, with a slightly longer length. In other words, there may be a gap of any desired width, such as a gap with a width in the range of about 0.2 mm to about 10 mm, such as in the range of about 0.8 mm to about 6 mm in the lateral directions, i.e. perpendicular to the longitudinal direction, between the seed layer and the perimeter heater.

The perimeter heater may comprise an electrical heating element. For example, suitable inductive heating elements may include, without limitation, a fluid cooled coil, such as a water or gas cooled coil. The coil may be made of copper or another material that may be refractory to at least the melting temperature of the material of the ingot, such as silicon. In some embodiments, no cooling may be necessary, and the heating element may be a solid length of a suitable material. The two ends of the perimeter heater may be connected to a power supply comprising an AC-power source and/or, optionally, a DC-power source.

The inductive perimeter heater may form an electromagnetic containment coil. The magnetic field produced by the perimeter heater may induce countercurrents in the conductive liquid silicon. The heater current and silicon countercurrent may interact through electromagnetic forces, and lead to a repulsion of the liquid silicon away from the heater. Operating the apparatus in such a manner may allow the perimeter heater to control the cross-section of the ingot to be produced in a nearly conformal manner via a contactless control of the ingot cross-section.

In some embodiments, the apparatus may comprise at least one perimeter cooler. The perimeter cooler may have an inner perimeter matching or nearly matching an outer perimeter of the seed layer in shape. In other words, there may be a gap of any desired width, such as a gap with a width in the range of about 0.2 mm to about 20 mm, such as in the range of about 2 mm to about 10 mm in the lateral directions, i.e., perpendicular to the longitudinal direction, between the seed layer and the perimeter cooler.

The perimeter cooler may be built as perimeter cooling loop. The perimeter cooler may comprise a tube containing a cooling fluid, such as, for example, a tube containing a cooling liquid or cooling gas that is being circulated through the tube. The perimeter cooling maybe spaced apart from the seed layer in the radial direction, for example such that it is not in physical contact with the ingot. In some embodiments, the perimeter cooler may form an edge cooling loop.

In some embodiments, the perimeter heater may be arranged above the perimeter cooler with a distance in the longitudinal direction of at most about 10 cm. In some embodiments, the perimeter heater may be arranged to be next to the perimeter cooler. For example, the perimeter heater may be arranged to be next to the perimeter cooler such that a distance to the perimeter cooler is at most about 5 cm, such as at most about 3 cm.

In some embodiments, the perimeter heater and the perimeter cooler may have the same or nearly the same cross-section in the lateral directions. The perimeter heater and the perimeter cooler may be arranged concentrically to the longitudinal axis that penetrates the center of the cross-section, but with a longitudinal offset as described above. Apart from the connections, the perimeter heater and the perimeter cooler may display a rotational symmetry, such as a discrete, or four-fold, rotational symmetry. In some embodiments, the rotational symmetry may be two-fold, with a rectangular cross-section. In some embodiments, the cross-section may be rectangular or square such that it can be subdivided with minimal waste into one or more rectangular or square bricks, such as, for example, for the purpose of cutting substrates that can be arranged for efficient space-filling in a solar module.

In some embodiments, the perimeter heater and the perimeter cooler may not have the same or nearly the same cross-section in the lateral directions. For example, the perimeter heater and the perimeter cooler may differ in diameter, with the perimeter heater placed above the liquid puddle while the perimeter cooler is placed next to the solid silicon.

In some embodiments, the apparatus further comprises a gas inlet as that at least one means for controlling the temperature field by supplying either cool or superheated gas directed at or in the vicinity of the phase boundary between the solidified ingot and the liquid layer of feedstock and where the strength of the gas jet stream can be rapidly modified in response to a signal measured (such as by a monitoring device) on the perimeter of the ingot as it rotates by. For example, in some embodiments, the at least one means for controlling the temperature field comprises one or more independently controlled gas inlets that supply a heated or superheated gas, such as one or more independently controlled gas inlets (that supply a heated or superheated gas) arranged near and/or above the rotatable support for the seed layer. For example, in some embodiments, the at least one means for controlling the temperature field comprises one or more independently controlled gas inlets that supply a cooled gas, such as one or more independently controlled gas inlets (that supply a cooled gas) arranged near and/or above the rotatable support for the seed layer.

The gas inlet may be suitable for introducing an inert gas, such as argon, from an inert gas reservoir. In some embodiments, the gas inlet may be arranged above the seed layer. In some embodiments, the gas inlet may be designed to allow an even flow of inert gas across the seed layer and/or the liquid material on top of the seed layer, respectively. In some embodiments, the gas inlet may comprise one or more independently controlled gas, such as one or more independently controlled gas inlets arranged near the rotatable support for the seed layer. For example, the one or more independently controlled gas inlets arranged near the rotatable support for the seed layer may be arranged above, above and to the side, directly to the side, and/or to the side and somewhat below the rotatable support for the seed layer.

In some embodiments, the feeding apparatus may comprise a means for melting silicon. The apparatus according to the present disclosure may comprise two or more different temperature control systems, such as, for example, one for melting the feedstock and one for the solidification thereof.

The feeding apparatus may be arranged outside the chamber. Thus, in embodiments were feedstock, such as a liquid feedstock, is introduced into the chamber of the apparatus of the present disclosure, the feedstock may be added to the chamber, such as to the seed layer, from outside the chamber.

In some embodiments, the apparatus is crucibleless.

In some embodiments, the feeding apparatus comprises an outlet, the position of the outlet relative to the seed layer being adjustable.

According to the methods of the present disclosure a seed layer, which optionally defines a cross-sectional area of an ingot to be produced, is provided on a rotatable support and the rotatable support is moved to a predetermined position within a temperature field with a predetermined vertical temperature gradient. Then, either an initial layer of silicon is melted to substantially cover the seed layer, or feedstock may be provided on the seed layer by way of a feeding apparatus, where the feeding of feedstock and the temperature field within a volume of growth are controlled such that the entire seed layer is covered with a layer of liquid silicon. Then, the rotatable support may be lowered (and optionally rotated), i.e., moved in a direction parallel to the temperature gradient, such as in the direction of decreasing temperature, as the layer of liquid feedstock solidifies due to the heat energy being removed from the bottom.

In other words, after the system is brought into initial equilibrium with a static, stable liquid layer above the seed layer, the thermal balance may be changed by decreasing the heating from above, increasing the cooling from below, or both. This may drive the solidification interface upwards, and the rotatable support layer is simultaneously drawn downward in an effort to maintain the solid/liquid interface within a given vertical range.

In some embodiments, the methods of the present disclosure may operate according to a feed-as-you-need principle.

In some embodiments, the temperature field in the volume of growth may be controlled such that the top surface of the seed layer assumes a temperature within about 100° C. of its melting temperature. The seed layer, for example, may assume a temperature within about 100° C. of its melting temperature at the beginning of the process, such as before feedstock is provided on the seed layer by the feeding apparatus. The top surface of the seed layer may be partially melted as part of the process initiation before additional liquid is provided. In some embodiments, a predetermined quantity (e.g., an amount sufficient to form an initial puddle) of solid feedstock may be placed on top of the seed layer before or during heat-up and it can then be melted at the beginning of the process, together with a portion of the top of the seed plate, to form an initial puddle.

In some embodiments, the vertical temperature gradient may be increased, i.e., the temperature gradient in the longitudinal direction during an initial phase may be increased, such as, for example, after the seed layer is substantially covered with a layer of melted material. The vertical temperature gradient may be increased in a way such that a solid-liquid phase boundary between the seed layer and the feedstock layer does not move. In other words, the vertical temperature gradient may be increased in a way such that there is no net solidification.

In some embodiments, the vertical temperature gradient may be kept mostly constant or even decreased at the beginning of crystal growth, with the heat balance changed to account for the removal of the heat of fusion by decreasing the heating from the top and/or increasing the cooling from the bottom.

In some embodiments, the amount of melted material delivered onto the seed layer may be adjusted such that the liquid layer stays at a height setpoint. The rate of providing melted feedstock onto the seed layer may be adjusted to keep the liquid height constant while the rotatable support is lowered and/or optionally rotated. The rate of providing feedstock may be adjusted to the magnitude of the net heat removal and the rate of lowering the rotatable support. For example, the height of the liquid phase may be kept constant at a value in the range of about 1 mm to about 10 cm, such as in the range of about 5 mm to about 2 cm, depending on the surface tension of the material. In some embodiments, the control may be managed such that the rate of pulling down is used to control the puddle height at the edge, for example, with decelerations in response to a lowering of puddle height and accelerations in response to increase in the puddle height. In some embodiments, the angle of contact between the liquid and the solid can be used as a proxy for puddle height.

In some embodiments, the feedstock may be provided by the feeding apparatus in form of liquid feedstock. For example, a liquid silicon feedstock may be provided at a temperature in the range of about 1410° C. to about 1500° C., such as a temperature in the range of about 1420° C. to about 1450° C. The feedstock may be provided onto the seed layer near the center of the seed layer with respect to its cross-section. In some embodiments, the feedstock may be provided onto the seed layer in a position that is off-center of the seed layer with respect to its cross-section. For example, in some embodiments in which the rotatable support and/or rotatable pedestal is rotated, the feedstock may or may not be provided onto the seed layer in a position that is off-center of the seed layer with respect to its cross-section.

In some embodiments, the containment of the liquid feedstock on the seed layer (otherwise based only on the liquid surface tension) may be aided by the electromagnetic field generated by a perimeter heater. For example, extra heat being induced by a perimeter heater may be countered by the perimeter cooler, such as by the perimeter cooling loop, which may be located just below the perimeter heater. The combination of the perimeter heater and the perimeter cooler may assist in defining the solidification front at the edge within a narrow space. Generally, the thermal gradient at the edge may be steeper than in the middle of the ingot due to the perimeter heater and cooler, but the shape of the solid-liquid interface may be tuned to be as flat as possible.

In some embodiments, a phase boundary between solidified ingot and liquid puddle may be held stationary while the rotatable support is lowered and/or optionally rotated.

In some embodiments, the arrangement of the components, such as the heaters and coolers, and by suitable control of the heaters and the coolers, a substantially flat phase boundary, i.e., a flat solidification interface may be maintained. In some embodiments, the arrangement of the components, such as the heaters and coolers, and by suitable control of the heaters and the coolers, a slight curvature at the perimeter of the solid/liquid interface, where the shape of the solid is concave at the edge but flatter in the middle, i.e., an interface with a slight curvature, may be maintained.

In some embodiments, at least one of the top heater and the bottom cooler are controlled such that the temperature field in the volume of growth has a lateral temperature gradient of about 5 K/cm, such as at most about 1 K/cm, or at most about 10 K/m or at most about 1 K/m.

In some embodiments, feedstock, such as liquid feedstock, may be continuously applied while the rotatable support is lowered and/or optionally rotated. For example, the feedstock may be continuously applied to keep the height of the liquid feedstock layer constant as the advancing solidification would otherwise tend to shorten the liquid layer from the bottom.

In some embodiments, for the adding of liquid feedstock from the feeding apparatus an outlet of said feeding apparatus may be adjusted to reach into the layer of liquid feedstock.

In some embodiments, the chamber may be evacuated or purged of air and back-filled with an inert gas, such as argon. For example, the chamber may be evacuated of air and back-filled with an inert gas, such as argon, at the beginning of the process, such as, before any melting has occurred and/or before any liquid feedstock is fed onto the seed plate.

In some embodiments, the temperature field is controlled in a manner such that a lateral temperature gradient in the volume of growth (V_{GR}) is at most about 5 K/cm.

In some embodiments, the apparatus may include a fluid heat exchanger that is capable of varying the heat extraction rate from the cooling apparatus from zero to full cooling power.

In some embodiments, the cross-sectional shape of the seed layer and perimeter heater are rectilinear, such as a cross-sectional shape having basically straight sides at roughly 90 degrees to one another and rounded corners with a radius of at least 1 mm and where the seed layer is laterally positioned to fit within the cross-section of the perimeter heater.

In some embodiments, the lateral size of the ingot may be controlled during growth by monitoring the gap between the seed crystal and the perimeter heater, and controlling the current in the perimeter heater as needed to increase or decrease the cross-sectional area of the liquid feedstock.

In some embodiments, the rate of solidification is actively controlled by monitoring the position of the liquid/solid interface and using an active feedback control loop on the net energy flux between the heating apparatus and the cooling apparatus.

In some embodiments, the feedstock material may include any desirable material, such as, for example, silicon, germanium, gallium arsenide, aluminum oxide, indium arsenide, silicon germanium, other semiconductors, polymers and transition metal oxides with a liquid phase.

In some embodiments, a predefined flow pattern may be generated in the layer of liquid feedstock by application of a time varying current to a top heating apparatus. For example, the time varying currents in the top heater are controlled such that at least during some periods the flow pattern in the layer of liquid feedstock is adjusted such that there is a flow of liquid feedstock from a central part of the layer to the corners.

In some embodiments, the solidifying layer of liquid feedstock may be monitored by a monitoring apparatus.

In some embodiments, depending on a signal from the monitoring apparatus an activation of at least one of the at least one means for controlling the temperature field in the volume of growth (V_{GR}), a rate of adding liquid feedstock from the feeding apparatus, an activation of a perimeter heater, an activation of a perimeter cooler, a rate of rotating the rotatable support and a rate of lowering the rotatable support may be controlled.

In some embodiments, depending on a signal from the monitoring apparatus the height of the layer of liquid feedstock may be adjusted. This adjustment may be global or it may pertain only to a certain portion of the solid/liquid interface.

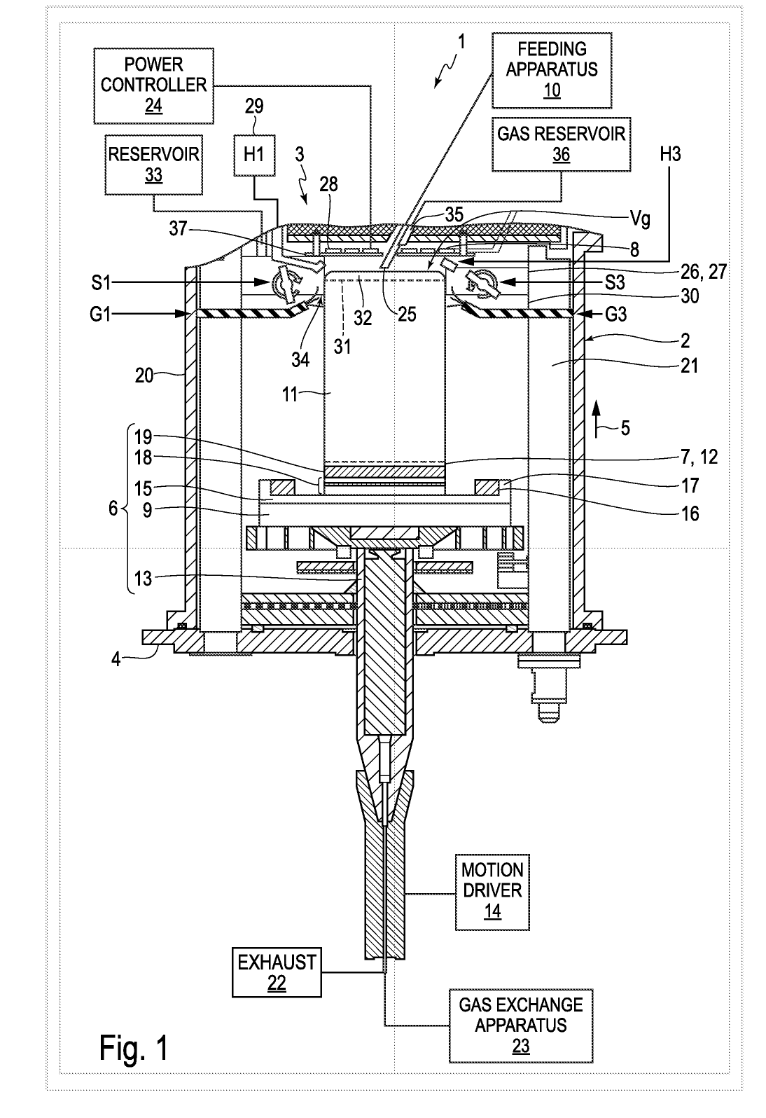

According to an embodiment shown in FIG. 1, an apparatus 1 for the production of ingots, in particular for the production of silicon ingots, comprises a chamber 2 to provide a controllable atmosphere. The chamber 2 has a top 3 and a bottom 4 spaced apart from each other in a longitudinal direction 5.

The bottom 4 of the chamber 2 is built as bottom plate. The top 3 is built as a lid, but could be configured as a thermal separation layer dividing the growth volume from the melting volume. The chamber 2 further comprises a sidewall 20, which extends primarily in the longitudinal direction 5. The side wall 20 preferably forms a gastight connection with the bottom 4 and optionally with the top 3. Along the sidewall 20 there is arranged a thermal insulation 21. The insulation 21 can be made of alumina fiber, carbon fiber, or any other suitable thermal insulator.

In the bottom 4 of the chamber 2 there is an exhaust 22. The chamber 2 is connected to a gas exchange apparatus 23 by way of the exhaust 22. It thus provides a controllable atmosphere. The gas exchange apparatus 23 can be a vacuum device to evacuate the chamber 2. In general, the gas exchange apparatus 23 forms a means for controlling the atmosphere inside the chamber 2.

Furthermore the apparatus 1 comprises a rotatable support 6 for supporting a seed layer 7 and a silicon block 11 solidifying on top of the seed layer 7. The rotatable support 6 is movable in the longitudinal direction 5 relative to the chamber 2.

The apparatus 1 further comprises a heating apparatus 8 and a cooling apparatus 9. The heating apparatus 8 and the cooling apparatus 9 may form a means for controlling a temperature field in a given volume of growth V_{GR} in the chamber 2. For example, the heating apparatus 8 and the cooling apparatus 9 may form a means for controlling a temperature field with a temperature gradient in the longitudinal direction 5.

In some embodiments, the at least one means for controlling the temperature field comprises one or more independently controlled heaters, such as for cooled or superheated gas supply (for example, H1 (and optionally H2, H3, and/or H4, not shown). In some embodiments, the one or more independently controlled heaters, may be arranged at any desired location, such as one or more independently controlled heaters arranged near and/or above the rotatable support for the seed layer.

The apparatus 1 also comprises an optional feeding apparatus 10 for controllable feeding of material onto the seed layer 7 or onto the already solidified silicon block 11 on the seed layer 7, respectively. In the latter case, it is also understood that the material is fed onto the seed layer 7.

The seed layer 7 may comprise one or more seed plates 12. The seed plates may be made of single crystal material, or may be ordered arrangements of crystals. The materials may be made of any desired material, such as silicon, or monocrystalline silicon. The one or more seed plates 12 may be cut from a single block of silicon.

In some embodiments, the seed layer 7 may have a cross-sectional area which corresponds to that of the ingots to be produced. For example, the seed layer 7 may have a cross-sectional that is circular, or rectangular, such as a square cross-sectional area with rounded corners. In some embodiments, the seed layer 7 may have an outer perimeter shape free of sharp corners, such as an outer perimeter shape with corner radii (r) of at least about 1 mm, such as at least about 3 mm.

The cross-sectional area of the seed layer 7 may have side lengths of any desired value, such as a side length in the range of from about 20 cm to about 80 cm, or a side length in the range of from about 30 cm to about 65 cm. In some embodiments, the side lengths may be integer multiples of side lengths of wafers to be cut from the ingot. In some embodiments, the seed layer 7 may have a cross-sectional area of at least 0.05 m², such as at least 0.2 m², in or at least 0.4 m².

The rotatable support 6 may comprise a rotatable pedestal 13. The rotatable pedestal 13 may be mechanically connected to a motion driver 14. If desired, the rotatable pedestal 13 may be rotated in a clockwise or counter clockwise manner by the motion driver 14. The rotatable pedestal 13 may be movable along the longitudinal direction 5 by the motion driver 14. In embodiments in which the ingot is rotated, the rotatable pedestal 13 may have any desired rotation speed, such as a rotation speed in the range of from about 0.1 rotations per minute to about 30 rotations per minute, or a rotation speed in the range of from about 1 rotation per minute to about 5 rotations per minute. The rotatable pedestal 13 may have any desired range of movement in the longitudinal direction 5, such as a range of movement in the longitudinal direction 5 of at least about 25 cm, or a range of movement in the longitudinal direction 5 of at least about 40 cm, or a range of movement in the longitudinal direction 5 of at least about 100 cm.

In some embodiments, ingots having any desired dimensions (for example, ingots of any desired length, such as a length of up to about five meters, or up to about 1 meter) may be made by transitioning to a side cooling mechanism above a certain ingot length and slowing down the growth speed.

In some embodiments, the pedestal column 13 may be configured to allow the passage of cooling fluid up to the cooling layer, 9. In some embodiments, the cooling block may radiate heat through a variable aperture to a fluid cooled surface, such as side wall 20 or bottom plate 4.

The rotatable support 6 may comprise a containment tray 15 with a circumferential edge 17. In some embodiments, the circumferential edge 17 may have a height in the longitudinal direction 5 of at least about 1 cm, in particular at least about 3 cm.

The containment tray 15 may have a cross-sectional area in the direction perpendicular to the longitudinal direction 5, which is at least 10% larger in cross-section, particularly as much as twice as large, in particular as much as three times as large as the cross-sectional area of the seed layer 7. The containment tray 15 may provide a volume for holding liquid material, such as liquid silicon. The volume may be at least 1 L, such as at least 2 L, or at least 3 L. In some embodiments, the containment tray may have any desired volume, such as a volume that is capable of holding the volume of feed material (for example, of silicon feed material) to be used in the apparatus, for example, a volume that is in a range of from about 110% to about 150% (such as about 110%) of that of the volume of feed material (for example, of silicon feed material) to be used in the apparatus such that the containment tray 15 may protect the lower part of the chamber 2 and the pedestal 13 from a spill of liquid feed material (for example, of liquid silicon).

In some embodiments, a sponge-like structure 16 may be arranged along the circumferential edge 17, and may fill the entire volume. The sponge-like structure 16 may form a sponge to soak up silicon present in the containment tray 15. In some embodiments, the sponge-like structure 16 may be formed in a manner (and formed of a suitable material) such that it may act as thermal insulation or a liquid barrier (in addition to soaking up silicon present in the containment tray 15).

The rotatable support 6 may optionally comprise a heater and insulator stack 18 arranged on top of the containment tray 15. For example, the heater and insulator stack 18 may be arranged between the cooling apparatus 9 and the seed layer 7.

The rotatable support 6 may comprise a support plate 19. The support plate 19 may be made of graphite or silicon carbide or silicon. The seed layer 7 may be arranged on top of the support plate 19.

In some embodiments, the seed layer 7 and the support plate 19 may have cross-sectional areas differing by at most 10%, in particular of at most 5%, in particular of at most 1%.

The cooling apparatus 9 may optionally be part of the rotatable support 6. In some embodiments, cooling apparatus 9 may be arranged in between the pedestal 13 and the containment tray 15.

The heating apparatus 8 may be arranged above the seed layer 7. The heating apparatus 8 is controllable by a power controller 24. In some embodiments, the heating apparatus 8 may be arranged on the opposite side of the seed layer 7 from the pedestal 13. The heating apparatus 8 can be inductive or resistive in type. The heating apparatus 8 may have an outer cross-sectional area in the direction perpendicular to the longitudinal direction 5, which is within 40% of the cross-sectional area of the seed layer 7, and may be slightly larger or smaller.

In some embodiments, the heating apparatus 8 may be designed to generate a temperature field with a negligible net lateral temperature gradient in the ingot. For example, the heating apparatus 8 may be designed to operate cooperatively with one or more additional heaters to generate a temperature field with a negligible net lateral temperature gradient in the ingot. The lateral temperature gradient in the ingot may be controlled to be at most about 5 K/cm, such as at most about 1 K/cm, or at most about 10 K/m or at most 1 K/m.

The heating apparatus 8 may be made of silicon carbide coated graphite. In some embodiments, heating apparatus 8 may be supported by a support layer 37, which may be made of any suitable material. For example, in embodiments where heating apparatus 8 is an inductive heating apparatus 8, the support layer 37 may be made of alumina or quartz; and in embodiments where heating apparatus 8 is a radiative heating apparatus 8, the support layer 37 may be made of silicon carbide (SiC), SiC-coated graphite or boron nitrite (BN) coated graphite.

A support layer 37 made of silicon carbide (SiC) or SiC-coated graphite may be fabricated in a way that the SiC does not shortcut heater loops. The support layer 37 may be electrically isolated from the heating apparatus 8. The support layer 37 may also serve to reduce the risk of contamination of the heating apparatus 8 with liquid silicon. In some embodiments, the heater may be suspended by its power leads and hang freely over the melt.

The cooling apparatus 9 may be configured to allow for a controlled variation in the magnitude or strength of heat removal. For example, the cooling apparatus 9 may form a cooling sink, or the cooling apparatus 9 may be built as heat exchanger block. In some embodiments, the cooling apparatus 9 may comprise active, controllable elements, including, for example, a means for enabling a controllable circulation of a cooling fluid within the heat exchanger block.

The cooling apparatus 9 may be designed such that a lateral temperature gradient in the volume of growth V_{GR} can be controlled to be at most about 5 K/cm, such as at most about 1 K/cm, or at most 10 K/m or at most 1 K/m.

The feeding apparatus 10 may comprise a feed tube 25 for feeding a liquid material, such as liquid silicon, onto the seed layer 7 or the already solidified silicon block 11, respectively. The feeding apparatus 10 may comprise a reservoir for holding liquid silicon and a means for melting silicon. The liquid silicon fed into the chamber 2 by the feeding apparatus 10 is referred to as feedstock for the silicon ingot to be produced.

In some embodiments, the apparatus 1 may comprise a perimeter heater 26. The perimeter heater depicted in FIG. 1 comprises a single-turn inductive heating coil 27. In some embodiments, the perimeter heater 26 may have an inner perimeter closely conforming to an outer perimeter of the seed layer 7, except at the corners of the cross-section, where the perimeter heater may diverge from the ingot. For example, there may be a gap 28 with a width in the range of about 0.2 mm to about 10 mm in between the outer perimeter of the seed layer 7 and the inner perimeter of the perimeter heater 26.

The heating coil 27 may be electrically connected to a power supply comprising an AC power source 29 and optionally a DC power source. In some embodiments, the heating coil 27 may be a water-cooled copper coil. In some embodiments, the heating coil 27 may be a refractory material capable of carrying the AC power from the AC power source 29 and operating at elevated temperatures, such as at temperatures up to at least the melting temperature of the silicon, or up to at least about 1450° C. The gap 28 between the liquid and the heater may be controlled by the strength of the magnetic field, which may be controlled by the current applied to the heater. Because the radius of the liquid surface is smaller at the corners, and the electromagnetic field is also enhanced, the space gap between the perimeter heater and the liquid may increase in the corners. This may be compensated by shaping the perimeter heater to bulge out at the corners, diverging from the seed crystal shape there. An observation device looking at the gap may be placed into feedback with the perimeter heater power to maintain the gap spacing within a desired control range.

In some embodiments, the apparatus 1 may comprise a perimeter cooler 30. The perimeter cooler 30 may be designed as a cooling loop that is located just below an intended solidification line 31, i.e. a phase boundary between the already solidified silicon block 11 and a layer 32 of liquid feedstock on top of that. The perimeter cooler 30 may be used to closely control the thermal gradient at the solidification front. For example, the perimeter cooler 30 may comprise a tube which is in fluid connection to a reservoir 33 for a cooling fluid, such as a cooling liquid or cooling gas. This cooling fluid may circulate through the tube of the perimeter cooler 30.

The perimeter cooler 30 may be arranged adjacent to the perimeter heater 26 in the longitudinal direction 5. In some embodiments, the perimeter cooler 30 may be arranged just below the perimeter heater 26. In some embodiments, the perimeter cooler 30 may be arranged above the perimeter cooler 30 with a distance in the longitudinal direction 5 of at most about 10 cm, such as at most about 5 cm, or at most about 3 cm.

The perimeter cooler 30 may have an identical inner cross-sectional area as the perimeter heater 26, or it may more closely conform to the ingot shape. In some embodiments, the perimeter cooler 30 may have an inner perimeter congruent with the outer perimeter of the seed layer 7. For example, there may be a gap 34 with a width in the range of about 0.2 mm to about 10 mm in a lateral direction between the perimeter cooler 30 and the outer perimeter of the seed layer 7 or the already solidified silicon block 11, respectively. In other words, the perimeter cooler 30 may be spaced apart from the silicon block 11 and thus not in direct physical contact with the silicon block 11.

In some embodiments, the apparatus 1 further comprises one or more gas inlet 35, such as a gas inlet that is connected to a gas reservoir, such as a temperature controlled gas reservoir. The gas inlet 35 may introduce an inert gas, such as argon, from the gas reservoir 36. In some embodiments, the gas inlet 35 may be arranged above the seed layer 7, such as, for example, at the top 3 of the growth chamber 2. In some embodiments, the gas inlet 35 may be designed to provide an even flow of an inert gas across the layer 32 of liquid silicon, for example, to sweep away silicon oxide (SiO) gas.

In some embodiments, the gas inlet may comprise one or more independently controlled gas inlets (for example, G1 and G3 (and optionally G2 and/or G4, not shown), such as one or more independently controlled gas inlets arranged near the rotatable support for the seed layer. For example, the one or more independently controlled gas inlets arranged near the rotatable support for the seed layer may be arranged, for example, above, above and to the side, directly to the side, and/or to the side and somewhat below either the rotatable support for the seed layer, the seed layer 7, silicon ingot 11, or the solid/liquid interface.

The apparatus 1 may be used in a method for the production of a silicon block 11, which is also referred to as silicon ingot 11. Although the method will be described for silicon, it also applies to a variety of other crystalline materials, semiconducting, insulating or metallic in nature.

In the methods of the present disclosure, an apparatus 1 according to the preceding description may be provided. For example, the chamber 2 with at least one means for controlling the temperature field with the temperature gradient in the longitudinal direction 5 in the volume of growth V_{GR} inside the chamber 2 and the rotatable support 6 for the seed layer 7 and the controllable feeding apparatus 10 may be provided. The seed layer 7 may be placed on the rotatable support 6.

In some embodiments, the seed layer 7, such as one or more seed plates 12 may be placed on the support plate 19 on top of the cooling apparatus 9. Then, the rotatable pedestal 13 may be brought up such that the seed layer 7 is close to the perimeter heater 26. For example, the seed layer 7 may be within a distance of at most about 1 cm to the perimeter heater 26, and the top of the seed layer may even exceed the height of the bottom of the perimeter heater. In some embodiments, the seed layer 7 may be arranged such that the lateral gap 28 is even on all sides of the seed layer 7.

The chamber 2 may be purged of air and back-filled with an inert gas, such as argon, by the gas exchange apparatus 23. The heating apparatus 8 may be turned on and controlled such that the seed layer 7, such as the at least one seed plate 12, is heated to within about 100° C. of the melting temperature, such as within 20° C. of the melting temperature of the seed layer.

In some embodiments, cooling by the cooling apparatus 9 from below can also be introduced, if desired, and a vertical temperature gradient may be established. For example, in some embodiments, the vertical temperature gradient may be kept low, such as at most up to a few tens of degrees per centimeter, or less than about 5 K/cm. In some embodiments, at least one of the heating apparatus 8 and/or the cooling apparatus 9 may be controlled such that the net lateral temperature gradient is as close to zero as possible. The net lateral temperature gradient in the volume of growth V_{GR} is kept below about 5 K/cm, such as below about 1 K/cm, or below about 1 K/m.

Then, either an initial layer of silicon is melted to substantially cover the seed layer, or silicon feedstock may be introduced from above by the feeding apparatus 10 via the feed tube 25, for example, in the center of the seed layer 7.

In some embodiments, the silicon feedstock may be introduced in a melted state, i.e. as a liquid. The feedstock may be doped to the desired resistivity. In some embodiments, feedstock may be introduced by the feeding apparatus 10 until a liquid layer 32 covers the entire seed layer 7, or the entire seed plate 12. For example, the feedstock may be introduced until the layer 32 has a liquid column height of a few millimeters up to several centimeters. In some embodiments, the liquid height of the layer 32 may be in the range of about 1 mm to about 5 cm, or a height in the range of about 3 mm to about 2 cm and optionally may have a uniform height over the entire cross-section. In some embodiments, the feedstock introduced may have a temperature in the range of 1410° C. to 1450° C.

The surface tension of silicon is sufficient to contain a liquid head height of the layer 32 up to about 6 mm to about 10 mm. To provide a layer 32 with a height larger than about 10 mm, electromagnetic containment through AC power supplied from the AC power source 29 to the perimeter heater 26 can be used. In some embodiments, an ingot may be produced without running the perimeter heater 26, such as if the liquid height of the layer 32 is kept below about 8 mm.

In some embodiments, the perimeter heater 26 may be run in feedback mode to control the lateral dimension of the solidifying silicon block 11.

Once the above conditions have been established and stabilized, the thermal gradient from the cooling sink, i.e. the cooling apparatus 9, can be increased in tandem with the heat from the heating apparatus 8 from above in order to maintain no net solidification. In other words, the vertical temperature gradient in the volume of growth V_{GR} can be increased in a way such that the solid-liquid phase boundary 31 between the seed layer 7 and the liquid layer 32 of feedstock does not move. The thermal gradient can be adjusted, in particular increased, until a given operating gradient has been reached and stabilized.

Then, the balance of heating and cooling may be shifted by a) increasing the cooling from below, b) decreasing the heating from above or c) both of the above.

Because of the net heat extraction, the liquid silicon begins to solidify and the solid/liquid interface starts to move up. At this point (or at any point during the heat-up), the rotatable pedestal 13 may be rotated to achieve a circular ingot cross-section and/or average out any abnormalities in the thermal field such that no one spot suffers from a hot spot or cold spot. Rotation of the ingot makes the overall dimension of the ingot simpler to control and the shape easier to maintain because no individual portion of a localized hot zone (or cold zone) will shape a particular portion of the crystal perimeter for a period of time long enough to have a deforming effect.

Rotation of the rotatable pedestal 13 also allows a simpler method for viewing the solidifying silicon block 11. The rotation has the positive effect of periodically sweeping the entire interface in front of any given perimeter location and thus instead of the three dimensional position of the solidification line 31 being monitored by a monitoring apparatus 40 having four separate cameras, a single camera with video analysis can monitor the entire ingot, which makes for a considerably simpler process automation scheme.

In some embodiments, the rotation of the rotatable pedestal 13 may or may not be combined with the convective gas cooling from one or more inert gas inlets, such as a single argon jet, directed towards the solid/liquid interface. For example, in embodiments where the growing ingot is rotated, as the growing ingot rotates, a base level of gas (e.g., such as about 1 L/min to about 10 L/min, or about 3 L/min to about 7 L/min, or about 5 L/min) from the one or more inert gas inlets may be directed towards the solid/liquid interface. In such embodiment, a monitoring apparatus 40 (such as a single camera) may be positioned to look at the interface just ahead of where the one or more gas jet is positioned. As the monitoring apparatus records the solid/liquid interface position, the rate of the cooling flow maybe varied to heat or cool that part of the solidifying silicon block 11 perimeter as it moves into the flow of the inert gas. In some embodiments, if an abnormality would form, such as a bulge, at one point in the solidifying silicon block 11 perimeter, a rapid, well-timed increase in the flow from the jet can be used to address the abnormality (that is, for example, by rapidly cooling the bulge as that part of the solidifying silicon block 11 passes by; or if a point on the perimeter is too cold and grows inwards, then the gas can be turned off altogether).

In some embodiments, a second or third gas inlet (such as a second or third jet) could be positioned at other radial positions and their flow rates varied based on the control signal and the rotation speed. For example, one or more of the gas inlets may be adapted to feed hot gas as desired, such as, in order to compensate and/or eliminate cold spots.

In some embodiments, for example, during very slow rotation of the rotatable pedestal 13, or while there is no rotation of the rotatable pedestal 13, one or more local heaters, such as a RF heater, that can be turned on and off may be used by positioning the one or more heaters near a point of the perimeter of the solidifying silicon block 11 to adjust the growing rate of the solidifying silicon block 11, as desired.

In some embodiments, the at least one means for controlling the temperature field may comprise one or more independently controlled movable insulation or heat shields (for example, S1 and S3 (and optionally S2 and/or S4, not shown). For example, in some embodiments, such as during very slow rotation of the rotatable pedestal 13, or while there is no rotation of the rotatable pedestal 13, one or more points of the perimeter of the solidifying silicon block 11 may be shielded with a movable piece of insulation such that one or more spots of the solidifying silicon block 11 would be protected by a window of insulation (that can move, for example, in any direction, such as up or down) to protect or expose a part of the perimeter of the solidifying silicon block 11 to more or less of a predetermined temperature environment (such as a local predetermined temperature environment created by heated or cooled gasses introduced by the one or more gas inlets). The movable insulation or heat shields may be made of any suitable material, such as, for example, alumina fiber, carbon fiber, or any other suitable thermal insulator.

In some embodiments, the rotatable pedestal 13 may be lowered to keep the bottom of the liquid layer 32 of feedstock at the same vertical level. At the same time, extra feedstock may be introduced from the top by the feeding device 10 to maintain the top of the liquid layer 32 within the desired control range. As the process proceeds, the rotatable pedestal 13 may be lowered to withdraw the seed layer 7 from the heating apparatus 8 and the feeding apparatus 10, as desired.

In some embodiments, the pedestal 13 may be lowered (and/or rotated) in a way such that the phase boundary 31 between the solidified silicon block 11 and the liquid layer 32 of feedstock is held stationary and abnormalities in the thermal field are averaged out by rotating the pedestal 13 at a rotation rate that is effective to ensure that no one spot of the solidified silicon block 11 suffers from a hot spot or cold spot.

By adding feedstock from the feeding apparatus 10 the liquid height of the layer 32 is kept constant while the pedestal 13 is lowered and/or rotated. In particular, feedstock may be continuously supplied while the rotatable support 6, in particular the pedestal 13, is lowered and/or rotated. In particular, feedstock may be continuously applied to keep the height of the liquid layer 32 of feedstock constant. In some embodiments, the solidification conditions in the volume of growth, such as at the phase boundary 31, may be kept quasi-static. This may be achieved by two different control schemes. In the first case, the heating and cooling balance may be kept to a set recipe over time and the rotatable pedestal 13 is moved in feedback with the solid/liquid interface position to maintain a quasi-static situation. In some embodiments, the rotatable pedestal 13 may be moved down according to a fixed schedule, and the heater 8 and/or cooling block 9 can be put into feedback with the solid/liquid interface position to maintain a given position.

While the silicon is solidified, a difference in heat flux between the heating apparatus 8 and the cooling apparatus 9 may be maintained to equal that of the heat of fusion of the solidifying silicon. In this way the entire cross-section may be solidified simultaneously, such as in a manner that maintains a very flat solidification line 31. The solidification line 31 may be flat to within less than about 15 mm, such as less than about 5 mm, or less than about 1 mm, in the longitudinal direction 5. In some embodiments, greater deflections may be used, for example, with slower growth rates to maintain dislocation-free growth.

Any extra heat being induced by the perimeter heater 26 can be countered by activation of the perimeter cooler 30 or by one or more of the localized temperature control mechanisms discussed above.

Once the body of the ingot has been solidified to the desired height, which can be, for example, up to more than about 1.5 meters, the feed of liquid silicon may be stopped and the liquid layer 32 is allowed to solidify in a controlled manner. Special care is applied to avoid liquid trapped by solid and dendritic structures. As the top surface of the ingot solidifies, the solid area radiates significantly more heat away than the liquid, due to the abrupt change in emissivity. Without a compensating adjustment, the remaining liquid will begin to be undercooled and may start to solidify dendritically, resulting in higher levels of stress and potentially in trapped liquid. It is possible to increase the heating from above during that phase in order to counter the higher radiated heat flux from the recently solidified material and maintain an orderly end to solidification, such as by moving either from the center out to the corners, or from the corners in to the center. In some embodiments, any edge cooling can be decreased during this segment, and edge heating may be increased.

At this point, the ingot may be cooled down to near room temperature and removed from the furnace. A new seed layer may be placed in and the process can start over.

There are several advantageous features of the apparatus and process. Foremost is the high purity of ingot that is attainable. The melted feedstock, once delivered, will at no point touch any non-silicon material, excepting the fresh, high purity argon being delivered across the surface. The lack of a crucible means that contaminant levels in the crystal (especially oxygen and iron) can be significantly below what is found in Czochralski and multicrystalline crystal growth methods. The fresh supply of argon sweeping the surface should serve to evaporate most of the oxygen present in the feedstock. This high purity can lead to enhanced minority carrier lifetime and improved solar cell efficiency levels.

In some embodiments, the uniform, unidirectional heat extraction from the bottom of the ingot allows the solidification of ingots with a cross section of several bricks (at least two and more preferably 4-16), growing the equivalent of 4-16 Cz ingots in parallel. Because of the lack of particulates in the process, together with a flat thermal gradient that minimizes stress concentration, linear growth rates in a range of from about 0.5 mm/min to about 2 mm/min that involves no crucible contact for the growing ingot and maintains single crystal structure.

Particulate control is favorable in this process as well. If small foreign particles do arrive on the liquid surface, it is likely that surface tension will keep them there. Normally, Marangoni convection would drive these particles along the surface towards the solid/liquid interface (i.e. the coldest point), but the presence of the induction current in the silicon perimeter should maintain these floating particles in the center of the liquid until such time as they are dissolved in the silicon. In such a way, these particles may increase dissolved impurity levels in the liquid, but should not cause the more serious destruction of the single crystal structure.

Concerning dislocations, it is believed that process of the present disclosure is capable of producing ingots with low levels, and even dislocation-free material. Furthermore, by controlling the shape of the phase boundary during crystallization of the ingot, it can be insured that the phase boundary is basically flat. It shows a bending of less than 5 mm. In particular, it shows a bending of less than 5 mm over an area of at least 156 mm×156 mm. This can also be seen from the wafers. The bending or deflection of the phase boundary can in particular be seen, measured and reconstructed from striations seen on the surface of the ingot and thus on the surface of the wafers. Such striations can be measured by lateral photovoltage scanning.

The wafers produced by the methods of the present disclosure may be such that the silicon of the wafers can have an interstitial oxygen content of less than about 5×10¹⁶ atoms per cm³, such as less than about 7×10¹⁷ atoms per cm³ and have a nitrogen content of less than about 1×10¹⁵ atoms per cm³. This includes single nitrogen atoms, nitrogen dimers N—N and triplets out of two nitrogen atoms and one oxygen atom N—N—O.

In some embodiments, the wafers produced by the methods of the present disclosure may have a square cross-section or pseudosquare cross section of any desired dimensions, such as a 100 mm to 200 mm square or pseudosquare wafer with L-shaped doping striations (i.e. ¼ of an NGM ingot), for example, where the L-shaped doping striations are concentric around one corner of the wafer.

In some embodiments, the wafers produced by the methods of the present disclosure may be a dislocation-free wafer having a square cross-section or pseudosquare cross section of any desired dimensions, such as a 100 mm to 200 mm square or pseudosquare wafer with non-centrosymmetric doping striations.

In some embodiments, the wafers produced by the methods of the present disclosure may have a square cross-section or pseudosquare cross section of any desired dimensions, such as a 100 mm to 200 mm square or pseudosquare wafer that is gallium-doped with an interstitial oxygen content of less than about 5×10¹⁶ atoms per cm³, such as less than about 7×10¹⁷ atoms per cm³, and doping striations that are not concentric to a point near the middle of the wafer.

In some embodiments, the wafers produced by the methods of the present disclosure may have a square cross-section or pseudosquare cross section of any desired dimensions, such as a 100 mm to 200 mm square or pseudosquare wafer that is gallium-doped with an interstitial oxygen content of less than about 5×10¹⁶ atoms per cm³, such as less than about 7×10¹⁷ atoms per cm³, and concentric doping striations centered on one corner of the wafer (optionally containing a dislocation density in the range of from about 10¹ to about 10⁴/cm²).

In some embodiments, the dislocation density of the wafers produced by the methods of the present disclosure may be in a range of from about 10 to about 1000 dislocations cm². Such wafers can also have an interstitial oxygen content of less than about 5×10¹⁶ atoms per cm³, such as less than about 7×10¹⁷ atoms per cm³ and have a nitrogen content of less than about 1×10¹⁵ atoms per cm³.

According to the present disclosure the ingots are large enough to divide them into four separate axially oriented columns, from which wafers can be cut. Since the striations as well as other structural and electrical properties of the ingots show a rotational symmetry with respect to a central longitudinal axis of the ingots, dividing the ingots into four columns will lead to square wafers, whose properties display a mirror symmetry with respect to one of their diagonals, in particular the striations on the wafer and the resistivity on the wafer can show such a symmetry with respect to one of the diagonals of the wafer.

In addition, since a bending of the phase boundary leads to a variability of the specific resistance across the cross sectional area of the ingot and thus the wafers cut from it, the wafers which are cut from the ingots produced according to the process according to the present disclosure have a low variability of the specific resistance across their surface. If the surface of the wafer is divided into four quarters, the variability of the specific resistance across the surface of a wafer may be in at least three quarters, in particular across the entire surface, less than about 5%, such as less than about 3%. The specific resistance can be in the range of from about 1 Ω·cm to about 5 Ωkm, or in the range of about 1.5 Ω·cm to about 3 Ωcm. Thus, the variation of the resistivity in at least three quarters, such as in all four quarters is less than about 0.25 Ωcm, such as less than about 0.1 Ωcm, or less than about 0.06 Ωcm.

The wafers may have a size of more than about (140 mm)², or more than about (156 mm)², or more than about (180 mm)², or more than about (200 mm)², or more than about (250 mm)², or more than about (300 mm)².

In some embodiments, the liquid height, volume and position are all basically static with respect to the heaters and/or insulation. For example, in order to maintain a quasi-static thermal gradient through the course of the process, the temperature of the cooling block may steadily decrease as it descends. Furthermore, to maximize the process stability, it is important to introduce the feedstock liquid in a way that minimally perturbs the liquid surface, and in as continuous a flow as possible. Due to the static melt volume, there may be no axial dopant concentration variation present in the major part of the ingot grown. Thus, the ingot has a constant, i.e. homogenous dopant concentration along its axis.

In the following further details of the apparatus 1 and alternative embodiments of some of its parts are described in U.S. Patent Application Publication Nos. 2014/0030501 and 2012/0235454, and U.S. patent application Ser. No. 14/058,708, the disclosures of each of which are incorporated by reference herein in their entirety.

The foregoing is further illustrated by reference to the following examples, which are presented for purposes of illustration and are not intended to limit the scope of the present disclosure.

### EXAMPLES

### Example 1

The following example describes the fabrication of a 100 mm-200 mm square or pseudosquare wafer with L-shaped doping striations.

A seed layer composed of one or more pieces of crystalline material is initially provided. The size of the seed layer is four to nine times the size of the wafer to be made. Here, a seed plate of 340 mm square and with an adequate thickness may be used. The seed layer has the crystalline structure (e.g., monocrystalline or multicrystalline with some advantageous crystal distribution) that is to be replicated in the newly formed ingot. For the purposes of this example, the use of a monocrystalline seed is described. The seed layer is to be placed with flat bottom onto a flat support plate in a crystal growth furnace, which has heat extraction from below and heaters above, in addition to a source of high purity feedstock. Then place 500 g of high purity silicon on top of the seed layer. Evacuate the furnace of air and back-fill it with argon. Next, bring up the power of the heaters and increase the heat extraction from the bottom jointly to create a roughly square thermal field on the seed layer. Melt the 500 g of silicon in the process of melting a puddle on the seed layer. Some of the top of the seed may also be melted. The edge of the puddle is defined by an isotherm at the melting point of the seed layer, and its shape conforms to the thermal field described earlier. The edge of the puddle is brought close to the edge of the seeds by management of the heater power. The puddle is doped with an impurity to create the desired resistivity in the resulting solid.

When the puddle is melted to a stable position, the flow of feedstock is begun from the source above. Then, provide melted feedstock from a tube, although it could be possible to provide solid feedstock in some circumstances. With the addition of more liquid material, the height of the liquid puddle increases and the tangent at the edge of the puddle comes closer to 90 degrees. At a point where the liquid puddle is sufficiently vertical at the edge, decrease the heating from above and increase the cooling from below, causing the liquid to solidify. Manage the heater power to maintain the height of the liquid puddle nominally constant, and manage the rate of downwards motion to keep the vertical position of the solid liquid interface within a small range. After the first centimeter or two of growth, the liquid puddle may be managed so that its tangent is 10 degrees past vertical (+/−2 degrees), which produces vertical walls on the growing ingot. The thermal field from the heater is the primary determiner of the crystal shape, which is nominally square. The dopant becomes incorporated into the silicon with a slightly varying rate, depending delicately on the puddle height, the pull rate and the convection in the liquid. After growing 25 cm, stop the flow of feedstock material, move slightly away from the supply tube and freeze out the remaining liquid in the puddle, maintaining the top heater and bottom cooling. The ingot is cooled using a recipe that minimizes residual stress. The ingot is then removed from the furnace and cut into four vertical blocks with square cross-section of 156 mm per side. If a pseudosquare is desired, then the corners can be ground down, if desired. The bricks may then be placed in a wire saw where they are cut into wafers. Each wafer contains doping striations incorporated as it was solidified. Those striations form three dimensional surfaces in the ingot. The wafer includes a slice of these surfaces, which can be visualized using sensitive electrical measurements of local resistivity. Laser Photovoltage Spectroscopy (LPS) may be used to image these striations. The striations reflect the square thermal field of the heater, so each brick (cut from one corner of the ingot), includes a set of L-shaped striations when a horizontal cross-section is done, such as in a cut wafer. Generally, the striations will be a set of nested L-shaped bands, concentric around the corner of the brick that was at the center of the ingot. In 9 brick ingots, four of the nine bricks will have this feature.

### Example 2

The following example describes the fabrication of a wafer with dislocations in a range of from about 10¹ dislocations/cm² to about 10⁴ dislocations/cm², oxygen of less than 7×10¹⁷ atoms/cm³ and nitrogen of less than 1×10¹⁵ atoms/cm³.

Begin with a seed layer as in Example 1, but in this example the seed layer has extra processing. The seed is made from a dislocation free single crystal and has only one piece in the layer. The seed is cut with a very high flatness on the bottom side, and may be ground for extra flatness. It is also etched to a depth (typically greater than 50 microns) that all surface damage from cutting processes is removed. The seed is placed on a seed holder (which for the purposes of this Example is graphite) with a similarly high flatness, such that the two surfaces have good contact across substantially the entire surface. No small pieces of debris or particulates should be in between the layers. A small amount of additional feedstock may be placed on top, preferably with wide, flat bottom surfaces. The seed is heated up as discussed above, but in this Example, the temperature is ramped up in a manner such that the net thermal gradient through the seed is less than approximately 40 K/cm. A strong purge of high purity argon gas is kept on the top surface of the seed to prevent surface reactions with reactive gases. The seed is melted as before and the liquid flow is started as before. The ingot is grown at speeds generally not exceeding 1.5 mm/min to avoid the formation of dendrites. No nitrogen is present in the furnace and the only contact of the ingot and melt puddle with quartz is through the partially submerged feed tube. Some dislocations may incorporate at the seeding interface or at the edge later in the ingot, but these dislocations do not multiply into dislocation cascades. Instead, they grow upwards singly until they meet an external surface. The feedstock may have some concentration of oxygen from quartz contact in the melter and melt tube, but the large liquid surface area being flushed by argon efficiently reduces the argon to levels below 7×10¹⁷ atoms/cm³. The ingot is solidified, cooled down and processed as described in Example 1. Oxygen may be measured on the wafer by methods such as Fourier Transform Infrared Spectroscopy (FTIR), where levels ranging from 1×10¹⁷ atoms/cm³ to 5×10¹⁷ atoms/cm³, and levels below 1×10¹⁷ are feasible. In the ingots that were produced, Nitrogen was undetectable by FTIR (i.e. below 1×10¹⁵ atoms/cm³), but trace levels in the 1×10¹⁴ atoms/cm³ range might be measured by Secondary Ion Mass Spectroscopy (SIMS). Dislocation density is measured by defect etching of the wafer followed by microscopy for etch pit density counting, where levels in the 10¹ to 10⁴ range were commonly observed.

### Example 3

This example describes the manufacture of a dislocation-free 100 mm-200 mm square or pseudosquare wafer with non-centrosymmetric doping striations.

The seed preparation and crystal growth proceeds as described in Example 2. Etching of the seeds was performed to remove up to 100 microns from all sides, and gas purging in the furnace was carried out. In addition to the purging of the top of the liquid surface, the sides of the seed were also purged with argon and the exhausted purge gas (containing SiO) is evacuated by a controlled path from the hot zone to prevent the recirculation of SiO and CO near the silicon. Furthermore, the materials for the parts in the vicinity of the silicon, and especially above the silicon, were specified to have inert surfaces. For example, all graphite was coated with a silicon carbide layer applied by chemical vapor deposition (CVD), and any insulation surfaces were covered either with CVD coatings or with thin coated graphite pieces. In this way, the incorporation of even small particles of foreign material into the melt was prevented. A smaller amount of feedstock (e.g. 200 g) for the initial puddle formation was used, preventing the sudden expansion of the melt puddle upon melting of the pieces. The ingot growth proceeded with the extra purging operational throughout the crystal growth. At the end of growth, a tail is grown on the crystal by decreasing the flow rate and decreasing the diameter in a controlled fashion. The angle of the cone was between 10 degrees and 30 degrees. In this way, should the dwindling melt puddle experience second phase precipitation (e.g. Si—Ga), any structure loss will be confined to the tail and will not extend backwards into the waferable part of the ingot. The bricks are cut as before and the L-shaped striations, roughly centered on one corner of the wafer (not in the center) are observed using LPS, as described in Example 1. Dislocation etching of the wafers reveals no dislocations incorporated in the course of the crystal growth, resulting in dislocation-free material.

### Example 4

### Round NGM

This example describes an experiment to create 100 mm-200 mm square or pseudosquare wafer with oxygen less than 7×10¹⁷ atoms/cm³ and concentric doping striations centered on one corner of the wafer (excludes 450 mm CZ). Begin with a seed layer composed of one or more pieces of crystalline material. The size of the seed layer is four to nine times the size of the wafer that will be made. A circular cross-section seed plate of 450 mm diameter having an adequate thickness is used in this Example. The seed layer has the crystalline structure (e.g. monocrystalline or multicrystalline with some advantageous crystal distribution) that is to be replicated in the newly formed ingot. In this Example, the use of a monocrystalline seed is described. The seed layer is placed with flat bottom onto a flat support plate in a crystal growth furnace, which has heat extraction from below and heaters above, in addition to a source of high purity feedstock. 500 g of high purity silicon is placed on top of the seed layer. Evacuate the furnace of air and back-fill it with argon. Bring up the power of the heaters and increase the heat extraction from the bottom jointly to create a roughly circular thermal field on the seed layer. At some point before the melting point is reached, rotation of the pedestal holding the seed plate is initiated. Melt the 500 g of silicon in the process of melting a puddle on the seed layer (some of the top of the seed is also melted). The edge of the puddle is defined by an isotherm at the melting point of the seed layer, and its shape conforms to the thermal field described earlier, aided in its circularity by the rotation. The edge of the puddle is brought close to the edge of the seed layer by management of the heater power. For this Example, the initial puddle was melted such that it was slightly over the edge of the seed crystal. The puddle is doped with an impurity to create the desired resistivity in the resulting solid.

When the puddle is melted to a stable position, the flow of feedstock is begun from the source above. Melted feedstock is provided from a tube (although it could be possible to provide solid feedstock in some circumstances). With the addition of more liquid material, the height of the liquid puddle increases and the tangent at the edge of the puddle comes closer to 90 degrees. At a point where the liquid puddle is sufficiently vertical at the edge, decrease the heating from above and increase the cooling from below, causing the liquid to solidify. The heater power is managed to maintain the height of the liquid puddle nominally constant, and the rate of downwards motion is managed to keep the vertical position of the solid liquid interface within a small range. After the first centimeter or two of growth, the liquid puddle is managed so that its tangent is 10 degrees past vertical (+/−2 degrees), which produces vertical walls on the growing ingot. The thermal field from the heater is the primary determiner of the crystal shape, which is nominally round. The dopant becomes incorporated into the silicon with a slightly varying rate, depending delicately on the puddle height, the pull rate and the convection in the liquid. After growing 25 cm, stop the flow of feedstock material, move slightly away from the supply tube and freeze out the remaining liquid in the puddle, maintaining the top heater and bottom cooling. The ingot is cooled using a recipe that minimizes residual stress. The ingot is then removed from the furnace and cut into four vertical blocks with square cross-section of 156 mm per side. If a pseudosquare is desired, then the corners can be ground down, if desired. The bricks are then placed in a wire saw where they may be cut into wafers. Each wafer contains doping striations incorporated as it was solidified. Those striations form three dimensional surfaces in the ingot. The wafer includes a slice of these surfaces, which can be visualized using sensitive electrical measurements of local resistivity. Laser Photovoltage Spectroscopy (LPS) may be used to image these striations. The striations reflect the round thermal field of the heater, so each brick (cut from one corner of the ingot), includes a set of arc-shaped striations when a horizontal cross-section is done, such as in a cut wafer. Generally, the striations observed were a set of nested quarter-circle bands, concentric around the corner of the brick that was at the center of the ingot. In 9 brick ingots that were produced, four of the nine bricks will have this feature, while another four will have circular arc sections centered off the center of an edge.

### Example 5

This example describes how we make 100 mm-200 mm square or pseudosquare wafers with concentric doping striations centered on one corner of the wafer and containing a dislocation density between 101/cm² and 104/cm².

The techniques to do this are similar to the previous Example, where an ingot of approximately 450 mm diameter and 20-50 cm was made. Some sporadic dislocations may be incorporated in the crystal, but because of the control of the thermal gradient and the curvature of the solid-liquid interface, in this Example, these dislocations do not lead to dislocation multiplication and eventual structure loss. Instead, a low to moderate dislocation density was observed in the wafers (e.g. by selective defect etching), while doping striations reflect the brick's position as one quarter of the overall crystal.

### Example 6

This example describes a method to produce a gallium-doped, 100 mm-200 min square or pseudosquare wafer with oxygen less than 7×10¹⁷ atoms/cm³ and doping striations that are not concentric to a point near the middle of the wafer. Here, a crystal growth method similar to examples 1-5 was used, where the ingot is formed from a puddle that is fed from the top and frozen up from the bottom. In the initial puddle, a quantity of gallium was included. This can be done by placing a small amount of high purity gallium (e.g. 100 mg) on top of the seed. The gallium will melt and sit on top of the silicon until the silicon itself melts, when it will mix very evenly. Because gallium has a much higher solubility in liquid silicon compared with solid silicon, only a small fraction of the gallium partitions into the solid, resulting in a very even axial concentration profile. After cutting bricks and wafers from the ingot, the gallium concentration can be measured by Gas Discharge Mass Spectroscopy or Inductively Coupled Plasma Mass Spectroscopy, the oxygen by FTIR and the doping striations by LPS.

Although the preceding description has been described herein with reference to particular means, materials and embodiments, it is not intended to be limited to the particulars disclosed herein; rather, it extends to all functionally equivalent structures, methods and uses, such as are within the scope of the appended claims. Furthermore, although only a few example embodiments have been described in detail above, those skilled in the art will readily appreciate that many modifications are possible in the example embodiments without materially departing from the disclosure of APPARATUS AND METHODS FOR PRODUCING SILICON-INGOTS. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures.

What is claimed is:

1. An apparatus for the production of ingots comprising:
a chamber to provide a controllable atmosphere, wherein the chamber has a top and a bottom spaced apart from each other in a longitudinal direction;
a rotatable support for supporting a seed layer, wherein the rotatable support is movable in the longitudinal direction relative to the chamber,
at least one means for controlling a temperature field in a given volume of growth (V_{GR}) in the chamber, wherein the temperature field has a temperature gradient in the longitudinal direction, and
a feeding apparatus for controllable feeding of material onto the seed layer.

2. The apparatus according to claim 1, wherein the at least one means for controlling the temperature field comprises one or more independently controlled heaters arranged above the rotatable support for the seed layer.

3. The apparatus according to claim 1, wherein the at least one means for controlling the temperature field comprises one or more independently controlled movable insulation or heat shields.

4. The apparatus according to claim 1, wherein the at least one means for controlling the temperature field comprises one or more independently controlled gas inlets arranged near the rotatable support for the seed layer.

5. The apparatus according to claim 1, wherein the at least one means for controlling the temperature field comprises at least one top heating apparatus arranged above the rotatable support for the seed layer, wherein the top heating apparatus is designed to generate a temperature field with a temperature gradient in a direction perpendicular to the longitudinal direction.

6. The apparatus according to claim 1, wherein the at least one means for controlling the temperature field comprises at least one cooling apparatus.

7. The apparatus according to claim 1, wherein the at least one cooling apparatus comprises one or more independently controlled gas inlets arranged near the rotatable support for the seed layer.

8. The apparatus according to claim 1, wherein the at least one cooling apparatus comprises at least one bottom cooling apparatus arranged below the rotatable support for the seed layer.

9. The apparatus according to claim 1, wherein the apparatus is crucibleless.

10. A method for the production of ingots comprising:
providing an apparatus, the apparatus comprising:
a chamber to provide a controllable atmosphere,
at least one means for controlling a temperature field with a temperature gradient in a longitudinal direction in a given volume of growth (V_{GR}) inside the chamber,
a rotatable support for a seed layer, the rotatable support being movable in the longitudinal direction inside the chamber, and
a controllable feeding apparatus for providing feedstock;
providing a seed layer on the rotatable support, wherein the seed layer has a predetermined cross-sectional area;
moving the rotatable support, such that the seed layer is located at a predetermined position within the volume of growth (V_{GR});
generating a temperature field with a predetermined vertical temperature gradient within the volume of growth (V_{GR});
providing an initial layer of melted silicon to substantially cover the seed layer;
rotating and lowering the rotatable support while solidifying the layer of liquid feedstock to form an ingot having a cross-sectional area; and
adding more liquid feedstock from the feeding apparatus.

11. The method according to claim 10, wherein a phase boundary between the ingot and liquid layer of feedstock is held substantially stationary while the rotatable support is rotated and lowered.

12. The method according to claim 10, wherein feedstock is continuously supplied while the rotatable support is rotated and lowered.

13. The method according to claim 10, wherein an average diameter of the predetermined cross-sectional area of the seed layer is smaller than an average diameter of the cross-sectional area of the ingot.

14. The method according to claim 10, wherein an average diameter of the predetermined cross-section of the seed layer is at least about 5% smaller than an average diameter of the cross-section of the ingot.

15. The method according to claim 10, wherein an average diameter of the predetermined cross-section of the seed layer is larger than an average diameter of the cross-section of the ingot.

16. The method according to claim 10, wherein an average diameter of the predetermined cross-section of the seed layer is at least about 5% larger than an average diameter of the cross-section of the ingot.

17. The method according to claim 10, further comprising independently controlling a growth behavior of the positions on the perimeter of an ingot.

18. The method according to claim 17, wherein the growth behavior of the perimeter of the ingot is controlled by one or more independently controlled heaters positioned near the edge of the ingot that rapidly heat up and cool down to provide phase boundary adjustments to different parts of the perimeter as the ingot rotates by the heater.

19. The method according to claim 17, wherein the growth behavior of the perimeter of the ingot is controlled by positioning one or more independently movable insulation or heat shields in the vicinity of one or more positions on the perimeter of the ingot in order to rapidly change the radiation view factor for different parts of the perimeter as they pass by the moving parts.

20. The method according to claim 17, wherein the growth behavior of the perimeter of the ingot is controlled by positioning one or more independently controlled gas inlets supplying either cool or superheated gas directed at or in the vicinity of the phase boundary between the solidified ingot and the liquid layer of feedstock and where the strength of the gas jet stream can be rapidly modified in response to a signal measured on the perimeter of the ingot as it rotates by.
